(19) United States
(12) Patent Application Publication
(10) Pub. No.: US 2026/0338533 A1
(43) Pub. Date: Oct. 29, 2026

(54) PIEZOELECTRIC SENSOR

(71) Applicant: Murata Manufacturing Co., Ltd., Nagaokakyo-shi (JP)

(72) Inventors: Hiroaki KITADA, Nagaokakyo-shi (JP); Takashi Kihara, Nagaokakyo-shi (JP); Keisuke Nishimoto, Nagaokakyo-shi (JP)

(21) Appl. No.: 19/704,682

(22) Filed: Jun. 11, 2026

Related U.S. Application Data
(63) Continuation of application No. PCT/JP2024/040930, filed on Nov. 19, 2024.

(30) Foreign Application Priority Data
Dec. 20, 2023 (JP) 2023-215119

(51) Int. Cl. G01B 7/16

(52) U.S. Cl. CPC G01B 7/16

(57) ABSTRACT

A piezoelectric sensor that includes: an insulating base material having a first main surface and a second main surface; a plurality of electrodes including a first electrode on the first main surface; and a piezoelectric film having a third main surface and a fourth main surface and disposed such that the fourth main surface faces the first electrode. In a region where the insulating base material and the piezoelectric film overlap each other in a plan view, the plurality of electrodes do not overlap each other in the plan view.

### CROSS REFERENCE TO RELATED APPLICATIONS

The present application is a continuation of International application No. PCT/JP2024/040930, filed Nov. 19, 2024, which claims priority to Japanese Patent Application No. 2023-215119, filed Dec. 20, 2023, the entire contents of each of which are incorporated herein by reference.

### TECHNICAL FIELD

The present disclosure relates to a piezoelectric sensor that detects deformation.

### BACKGROUND ART

As an disclosure related to a conventional piezoelectric sensor, for example, a piezoelectric sensor described in Patent Document 1 is known. The piezoelectric sensor described in Patent Document 1 is disposed on an inner wall surface of a cylindrical housing, is pressed from an outer peripheral side surface (pressing surface) of the housing, and detects deformation due to the pressing. The piezoelectric sensor described in Patent Document 1 includes an insulating base material having two main surfaces facing each other, a first electrode, a second electrode, a piezoelectric film having an upper surface and a lower surface, and a conductive thin film member. The first electrode and the second electrode are formed on both main surfaces of the insulating base material, respectively. The second electrode is attached to the inner wall surface of the housing with an adhesive or the like. The lower surface of the piezoelectric film is attached to the upper surface of the first electrode. A conductive thin film member is attached to the upper surface of the piezoelectric film.
Patent Document 1: WO 2016/194690 A

### SUMMARY OF THE DISCLOSURE

In the piezoelectric sensor described in Patent Document 1, when the thickness of the insulating base material varies, the sensitivity of the piezoelectric sensor to deformation changes, and the detection accuracy of the piezoelectric sensor to deformation may decrease.

Therefore, an object of the present disclosure is to provide a piezoelectric sensor capable of suppressing a change in sensitivity to deformation due to a variation in thickness of an insulating base material.

A piezoelectric sensor according to an embodiment of the present disclosure includes: an insulating base material having a first main surface and a second main surface; a plurality of electrodes including a first electrode on at least on the first upper main surface; a piezoelectric film having a third main surface and a fourth main surface, the piezoelectric film being disposed such that the fourth main surface faces the first electrode, in which in a region where the insulating base material and the piezoelectric film overlap each other in a plan view, the plurality of electrodes do not overlap each other in the plan view.

When the piezoelectric sensor is deformed by pressing or the like with respect to the normal direction of the insulating base material, the upper main surface of the piezoelectric sensor contracts, and the lower main surface expands. In the structure of the piezoelectric sensor described in Patent Document 1, the position of the insulating base material in a sectional view is close to the center position of the thickness of the piezoelectric sensor. Therefore, in the structure of the piezoelectric sensor described in Patent Document 1, the neutral surface (non-stretchable portion) of the stress of the piezoelectric sensor is located on the insulating base material. Therefore, in the structure of the piezoelectric sensor described in Patent Document 1, the sensitivity of the piezoelectric sensor greatly changes due to the variation in the thickness of the insulating base material. In contrast, in the piezoelectric sensor according to an embodiment of the present disclosure, in a region where the insulating base material and the piezoelectric film overlap in plan view, the plurality of electrodes do not overlap each other in plan view, so that the neutral surface of stress is not located on the insulating base material when the piezoelectric sensor is pressed. Further, when the piezoelectric sensor is pressed, it is possible to prevent the insulating base material from being positioned in a range from the piezoelectric film to the neutral surface of the stress. Thus, according to the piezoelectric sensor according to an embodiment of the present disclosure, it is possible to suppress a change in sensitivity to deformation due to a variation in thickness of the insulating base material.

According to the present disclosure, it is possible to suppress a change in sensitivity to deformation due to a variation in thickness of the insulating base material.

### BRIEF EXPLANATION OF THE DRAWINGS

FIG. 1 is a perspective view of a piezoelectric sensor 1.

FIG. 2 is an exploded perspective view of the piezoelectric sensor 1.

FIG. 3 is a plan view of a first electrode 3, a second electrode 4, and a third electrode 5 as viewed in a downward direction.

FIG. 4 is a plan view of a shield tape 11 as viewed in a downward direction.

FIG. 5 is a plan view of a shield film 7 as viewed in an upward direction.

FIG. 6 is a perspective view of a piezoelectric sensor 50 according to a comparative example.

FIG. 7 is a sectional view of the piezoelectric sensor 50.

FIG. 8 is a sectional view of the piezoelectric sensor 1.

FIG. 9 is a schematic sectional view of the piezoelectric sensor 50 and the piezoelectric sensor 1 in a first simulation.

FIG. 10 is a diagram illustrating a strain amount of each member in the first simulation of the piezoelectric sensor 50.

FIG. 11 is a diagram illustrating a strain amount of each member in the first simulation of the piezoelectric sensor 1.

FIG. 12 is a diagram illustrating a change in sensitivity of the piezoelectric sensor 50 and the piezoelectric sensor 1 with respect to a change in thickness of each member of the piezoelectric sensor 50 and the piezoelectric sensor 1 in the first simulation.

FIG. 13 is an example of a diagram illustrating the strain amount of each member in a second simulation of the piezoelectric sensor 1.

FIG. 14 is an example of a diagram illustrating the strain amount of each member in the second simulation of the piezoelectric sensor 1.

FIG. 15 is an exploded perspective view of a piezoelectric sensor 1a.

FIG. 16 is a plan view of the piezoelectric sensor 1a.

FIG. 17 is a sectional view taken along line A-A in FIG. 16.

FIG. 18 is a sectional view taken along line B-B in FIG. 16.

FIG. 19 is a diagram illustrating a strain amount of each member in a third simulation of the piezoelectric sensor 1a.

FIG. 20 is a diagram illustrating a strain amount of each member in a simulation of the piezoelectric sensor 1 when the pressed portion overlaps the second electrode 4 as viewed in the vertical direction.

FIG. 21 is a plan view illustrating a range in which the second electrode 4 and a piezoelectric film 10 overlap each other as viewed in the upward direction.

### DESCRIPTION OF THE PREFERRED EMBODIMENTS

### First Embodiment

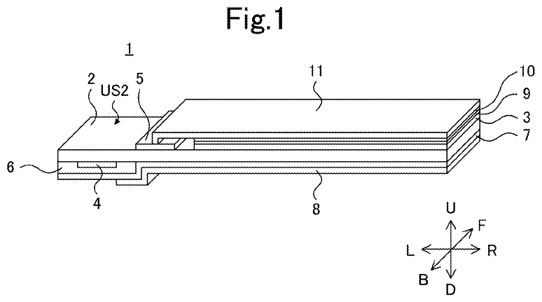

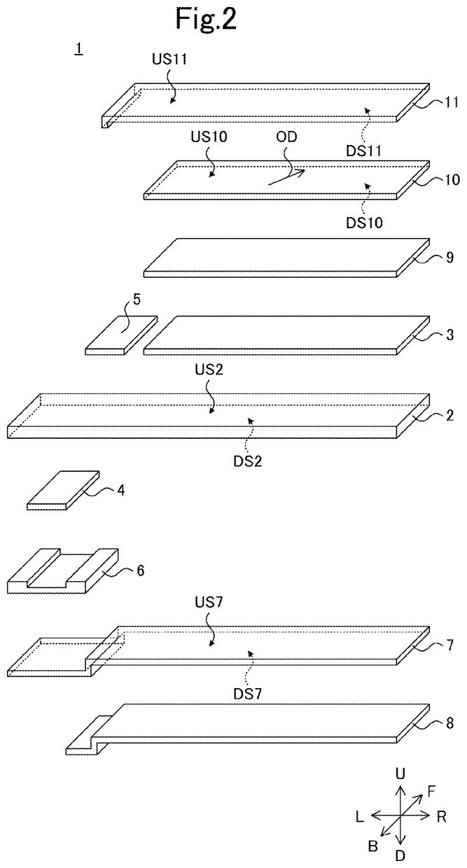

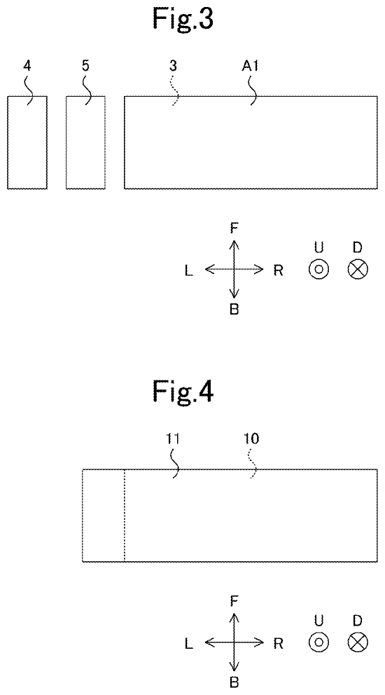

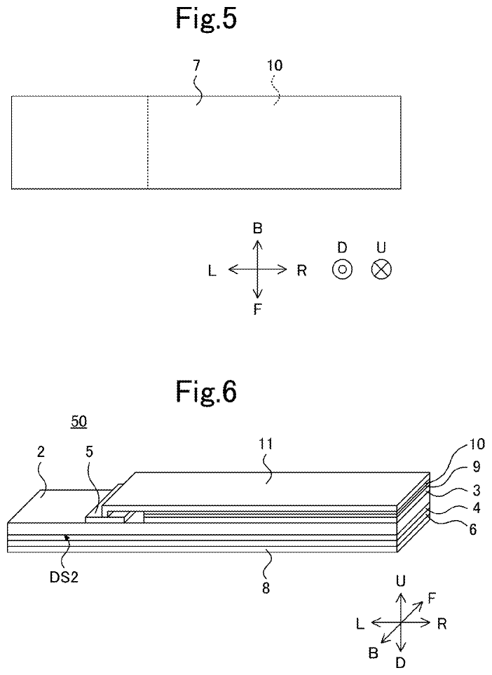

Hereinafter, a configuration of a piezoelectric sensor 1 according to a first embodiment of the present disclosure will be described with reference to the drawings. FIG. 1 is a perspective view of a piezoelectric sensor 1. FIG. 2 is an exploded perspective view of the piezoelectric sensor 1. FIG. 3 is a plan view of a first electrode 3, a second electrode 4, and a third electrode 5 as viewed in a downward direction. FIG. 4 is a plan view of a shield tape 11 as viewed in a downward direction. FIG. 5 is a plan view of a shield film 7 as viewed in an upward direction.

In the present specification, directions are defined as follows. As illustrated in FIG. 1, a direction in which the long side of an upper main surface US2 of an FPC 2 extends is defined as the left-right direction. A direction in which the short side of the upper main surface US2 of the FPC 2 extends is defined as a front-rear direction. A direction in which the FPC 2 and a piezoelectric film 10 are arranged is defined as a vertical direction. The left-right direction, the front-rear direction, and the vertical direction are orthogonal to each other. Viewing in the upward direction or the downward direction corresponds to “plan view” according to the present disclosure. However, the left-right direction, the front-rear direction, and the vertical direction in the present specification are directions defined for convenience of description, and may not coincide with the left-right direction, the front-rear direction, and the vertical direction when the piezoelectric sensor 1 is used. In each drawing, the left direction and the right direction may be interchanged, the front direction and the rear direction may be interchanged, or the upper direction and the lower direction may be interchanged.

The piezoelectric sensor 1 detects deformation of a measurement object. Further, the piezoelectric sensor 1 has high flexibility and can be flexibly deformed. As a result, even if the measurement object has irregularities, the piezoelectric sensor 1 can be brought into close contact with the measurement object. As illustrated in FIG. 2, the piezoelectric sensor 1 includes the FPC 2, the first electrode 3, the second electrode 4, the third electrode 5, a coverlay 6, a shield film 7, a double-sided tape 8, a hot melt 9, a piezoelectric film 10, and a shield tape 11. The piezoelectric sensor 1 is attached to the measurement object such that the piezoelectric film 10 is disposed immediately below a pressed portion of the measurement object. When viewed in the vertical direction, the FPC 2 overlaps the first electrode 3, the second electrode 4, the third electrode 5, the coverlay 6, the shield film 7, the double-sided tape 8, the hot melt 9, the piezoelectric film 10, and the shield tape 11. In the piezoelectric sensor according to the present disclosure, each of the third electrode 5, the coverlay 6, the shield film 7, the double-sided tape 8, the hot melt 9, and the shield tape 11 is not an essential component. The FPC 2, the shield film 7, the double-sided tape 8, the hot melt 9, and the shield tape 11 correspond to the “insulating base material”, the “second conductive thin film member”, the “third adhesive member”, the “first adhesive member”, and the “first conductive thin film member”, respectively, according to the present disclosure. The first electrode 3, the second electrode 4, and the third electrode 5 correspond to “a plurality of electrodes” according to the present disclosure.

The FPC 2 is an insulating base material having flexibility. The material of the FPC 2 is, for example, polyimide, poly ethylene terephthalate (PET), liquid crystal polymer, or the like. The FPC 2 has an upper main surface US2 and a lower main surface DS2 arranged in this order along the downward direction. Each of the upper main surface US2 and the lower main surface DS2 has a rectangular shape having two long sides extending in the left-right direction and two short sides extending in the front-rear direction. The upper main surface US2 and the lower main surface DS2 correspond to a “first upper main surface” and a “first lower main surface” according to the present disclosure, respectively. The shape and arrangement of the insulating base material according to the present disclosure are not limited to the shape and arrangement of the FPC 2.

The first electrode 3 is formed on the upper main surface US2 of the FPC 2. The upper surface and the lower surface of the first electrode 3 each have a rectangular shape having two long sides extending in the left-right direction and two short sides extending in the front-rear direction. The first electrode 3 functions as a signal electrode for outputting a potential difference generated by the piezoelectric film 10 as a charge. The shape and arrangement of the first electrode according to the present disclosure are not limited to the shape and arrangement of the first electrode 3.

The second electrode 4 is formed on the lower main surface DS2 of the FPC 2. The upper surface and the lower surface of the second electrode 4 each have a rectangular shape having two short sides extending in the left-right direction and two long sides extending in the front-rear direction. The second electrode 4 is connected to the ground potential. As a result, the second electrode 4 functions as a shield electrode. The shape and arrangement of the second electrode according to the present disclosure are not limited to the shape and arrangement of the second electrode 4.

In the piezoelectric sensor according to the present disclosure, the second electrode 4 is not an essential component. That is, the plurality of electrodes according to the present disclosure may be formed only on the upper main surface US2 of the FPC 2 without being formed on the lower main surface DS2 of the FPC 2.

The third electrode 5 is formed on the upper main surface US2 of the FPC 2. That is, in the present embodiment, the first electrode 3, the second electrode 4, and the third electrode 5 are formed on the upper main surface US2 and the lower main surface DS2 of the FPC 2. The upper surface and the lower surface of the third electrode 5 each have a rectangular shape having two short sides extending in the left-right direction and two long sides extending in the front-rear direction. In the present embodiment, the third electrode 5 is disposed on the left of the first electrode 3. The third electrode 5 is connected to the ground potential. As a result, the third electrode 5 functions as a shield electrode. The shape and arrangement of the third electrode according to the present disclosure are not limited to the shape and arrangement of the third electrode 5. In the piezoelectric sensor according to the present disclosure, the third electrode 5 is not an essential component.

The coverlay 6 has flexibility and insulating properties. The coverlay 6 is formed on the lower main surface DS2 of the FPC 2 so as to cover the second electrode 4. Thus, the coverlay 6 protects the second electrode 4. The material of the coverlay 6 is, for example, polyimide or the like. The shape and arrangement of the coverlay are not limited to the shape and arrangement of the coverlay 6.

The shield film 7 has flexibility and conductivity. The shield film 7 has a flat film shape. The shield film 7 has an upper main surface US7 and a lower main surface DS7 arranged in this order along the downward direction. The upper main surface US7 is disposed so as to face the lower main surface DS2 of the FPC 2. The shield film 7 covers the lower main surface DS2 of the FPC 2 and the coverlay 6 by being partially bent. The shield film 7 is connected to the ground potential. For connection of the shield film 7 to the ground potential, for example, an opening may be provided in the coverlay 6 to connect the shield film 7 to the second electrode 4. As a result, the shield film 7 functions as a shield conductor. The upper main surface US7 and the lower main surface DS7 correspond to a “fourth upper main surface” and a “fourth lower main surface” according to the present disclosure, respectively. The shape and arrangement of the second conductive thin film member according to the present disclosure are not limited to the shape and arrangement of the shield film 7.

The double-sided tape 8 has flexibility. The double-sided tape 8 has a flat film shape. An upper surface and a lower surface of the double-sided tape 8 have adhesiveness. The double-sided tape 8 is provided on the lower main surface DS7 of the shield film 7. The upper surface of the double-sided tape 8 is in close contact with the lower main surface DS7 of the shield film 7 by being partially bent. When the piezoelectric sensor 1 is in use, the lower surface of the double-sided tape 8 is brought into close contact with the measurement object to attach the piezoelectric sensor 1 to the measurement object. The shape and arrangement of the third adhesive member according to the present disclosure are not limited to the shape and arrangement of the double-sided tape 8.

The piezoelectric film 10 has flexibility. The piezoelectric film 10 has a flat film shape. The piezoelectric film 10 covers the upper surface of the first electrode 3. The piezoelectric film 10 has an upper main surface US10 and a lower main surface DS10 arranged in this order along the downward direction. The lower main surface DS10 is disposed so as to face the first electrode 3. The upper main surface US10 and the lower main surface DS10 each have a rectangular shape having two long sides extending in the left-right direction and two short sides extending in the front-rear direction when viewed in the vertical direction. The upper main surface US10 and the lower main surface DS10 correspond to a “second upper main surface” and a “second lower main surface” according to the present disclosure, respectively. The shape and arrangement of the piezoelectric film according to the present disclosure are not limited to the shape and arrangement of the piezoelectric film 10.

The piezoelectric film 10 is polarized by deformation to generate a potential difference between the upper main surface US10 and the lower main surface DS10. The potential difference generated between the upper main surface US10 and the lower main surface DS10 corresponds to the deformation amount of the piezoelectric film 10.

The piezoelectric film 10 is, for example, a film formed of a chiral polymer. The chiral polymer is, for example, polylactic acid (PLA) such as poly-L-lactic acid (PLLA) and poly-D-lactic acid (PDLA). A main chain of the PLA has a helical structure. The PLA has piezoelectricity by being uniaxially stretched to orient molecules. The piezoelectric film 10 has a piezoelectric constant of d14.

The PLA is stretched in the uniaxial stretching direction OD. The uniaxial stretching direction OD of the PLA forms an angle of 45 degrees with respect to each of the left-right direction and the front-rear direction. Note that 45 degrees may be within a range of about 45 degrees ±10 degrees. The piezoelectric film 10 is stretched or compressed along the left-right direction to generate a potential difference between the upper main surface US10 and the lower main surface DS10. Similarly, the piezoelectric film 10 is stretched or compressed along the front-rear direction to generate a potential difference between the upper main surface US10 and the lower main surface DS10. In the present embodiment, the magnitude of the potential difference generated between the upper main surface US10 and the lower main surface DS10 is proportional to the differential value of the deformation amount of the piezoelectric film 10.

The hot melt 9 has flexibility. The hot melt 9 is disposed between the lower main surface DS10 of the piezoelectric film 10 and the first electrode 3. The hot melt 9 has a flat film shape. The hot melt 9 has adhesiveness. The hot melt 9 is solid at normal temperature. When heated, the hot melt 9 melts and becomes a liquid. The hot melt 9 fixes the piezoelectric film 10 to the upper surface of the first electrode 3. The shape and arrangement of the first adhesive member according to the present disclosure are not limited to the shape and arrangement of the hot melt 9.

The shield tape 11 has flexibility and conductivity. The shield tape 11 has a flat film shape. The shield tape 11 has an upper main surface US11 and a lower main surface DS11 arranged in this order along the downward direction. The lower main surface DS11 of the shield tape 11 has adhesiveness. The shield tape 11 is disposed on the upper main surface US10 of the piezoelectric film 10. The lower main surface DS11 of the shield tape 11 is in close contact with the upper main surface US10 of the piezoelectric film 10. The shield tape 11 covers the upper main surface US10 of the piezoelectric film 10. Further, when the left end portion of the shield tape 11 is bent, the left end of the shield tape 11 comes into contact with the upper surface of the third electrode 5. Thus, the shield tape 11 is electrically connected to the third electrode 5. As a result, the shield tape 11 is connected to the ground potential. Therefore, the shield tape 11 functions as a shield conductor. In summary, in the present embodiment, the first electrode 3 functions as a signal electrode, and the second electrode 4, the third electrode 5, the shield film 7, and the shield tape 11 function as a shield conductor. The upper main surface US11 and the lower main surface DS11 correspond to a “third upper main surface” and a “third lower main surface” according to the present disclosure, respectively. The shape and arrangement of the first conductive thin film member according to the present disclosure are not limited to the shape and arrangement of the shield tape 11.

As illustrated in FIG. 3, in the present embodiment, the position and shape of a region A1 where the FPC 2 and the piezoelectric film 10 overlap when viewed in the vertical direction coincide with the position and shape of the first electrode 3 when viewed in the vertical direction. In the region A1 where the FPC 2 and the piezoelectric film 10 overlap when viewed in the vertical direction, the first electrode 3, the second electrode 4, and the third electrode 5 do not overlap each other when viewed in the vertical direction. That is, in the region A1 where the FPC 2 and the piezoelectric film 10 overlap when viewed in the vertical direction, the third electrode 5 does not overlap the first electrode 3 and the second electrode 4 when viewed in the vertical direction. In the present embodiment, as viewed in the vertical direction, the second electrode 4, the third electrode 5, and the first electrode 3 are arranged in this order along the right direction. Note that the second electrode 4, the third electrode 5, and the first electrode 3 do not necessarily need to be arranged in this order along the right direction when viewed in the vertical direction, and the first electrode 3, the second electrode 4, and the third electrode 5 are only required not to overlap each other when viewed in the vertical direction in the region A1 where the FPC 2 and the piezoelectric film 10 overlap each other when viewed in the vertical direction. That is, the first electrode 3, the second electrode 4, and the third electrode 5 may overlap each other when viewed in the vertical direction in a region other than the region A1 where the FPC 2 and the piezoelectric film 10 overlap each other when viewed in the vertical direction. In addition, the position and shape of the region A1 where the FPC 2 and the piezoelectric film 10 overlap when viewed in the vertical direction do not necessarily need to coincide with the position and shape of the first electrode 3 when viewed in the vertical direction.

As illustrated in FIG. 4, in the present embodiment, the shield tape 11 overlaps the entire piezoelectric film 10 when viewed in the vertical direction. When viewed in the vertical direction, the shield tape 11 may overlap only a part of the piezoelectric film 10.

As illustrated in FIG. 5, in the present embodiment, the shield film 7 overlaps the entire piezoelectric film 10 when viewed in the vertical direction. Note that the shield film 7 may overlap only a part of the piezoelectric film 10 when viewed in the vertical direction.

For the piezoelectric sensor 1 and a piezoelectric sensor 50 according to a comparative example, the inventor of the present application performed two types of simulations (hereinafter, the simulations are referred to as a first simulation and a second simulation, respectively) to confirm a change in sensitivity to deformation of the piezoelectric sensor due to a variation in thickness of the FPC 2. First, the piezoelectric sensor 50 according to the comparative example will be described with reference to the drawings. FIG. 6 is a perspective view of the piezoelectric sensor 50 according to the comparative example.

As illustrated in FIG. 6, the piezoelectric sensor 50 includes an FPC 2, a first electrode 3, a second electrode 4, a third electrode 5, a coverlay 6, a double-sided tape 8, a hot melt 9, a piezoelectric film 10, and a shield tape 11. The configuration of the piezoelectric sensor 50 conforms to the configuration of a piezoelectric sensor 20 described in Patent Document 1 (WO 2016/194690). Since the configuration of the piezoelectric sensor 50 above the FPC 2 is the same as the configuration of the piezoelectric sensor 1 above the FPC 2, the description thereof will be omitted.

The piezoelectric sensor 50 does not include the shield film 7. In the piezoelectric sensor 50, the second electrode 4 covers substantially the entire lower main surface DS2 of the FPC 2. The coverlay 6 covers substantially the entire lower surface of the second electrode 4. The double-sided tape 8 covers substantially the entire lower surface of the coverlay 6.

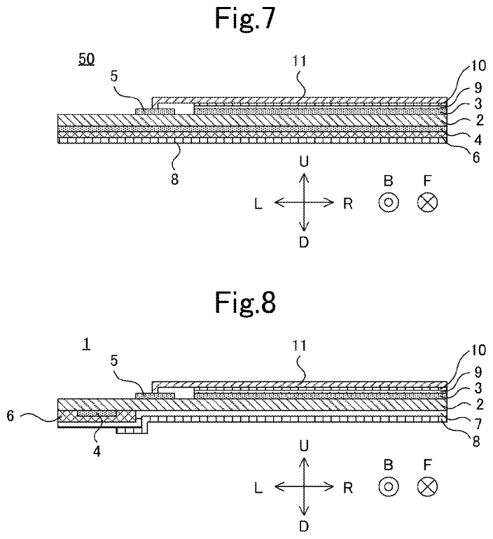

FIG. 7 is a sectional view of the piezoelectric sensor 50. As illustrated in FIGS. 6 and 7, in the piezoelectric sensor 50, in a region A1 where the FPC 2 and the piezoelectric film 10 overlap when viewed in the vertical direction, the first electrode 3 and the second electrode 4 overlap each other when viewed in the vertical direction. In the piezoelectric sensor 50, the second electrode 4 and the third electrode 5 overlap each other when viewed in the vertical direction. FIG. 8 is a sectional view of the piezoelectric sensor 1. In contrast, as illustrated in FIGS. 3 and 8, in the piezoelectric sensor 1, the first electrode 3, the second electrode 4, and the third electrode 5 do not overlap each other as viewed in the vertical direction in a region A1 where the FPC 2 and the piezoelectric film 10 overlap each other when viewed in the vertical direction.

Next, the first simulation and the second simulation will be described with reference to the drawings. The first simulation is a simulation for confirming a change in sensitivity to deformation due to a variation in the thickness of the FPC 2 for the piezoelectric sensor 50 and the piezoelectric sensor 1. The second simulation is a simulation for confirming the influence of the thickness of the double-sided tape 8 on the piezoelectric sensor 1.

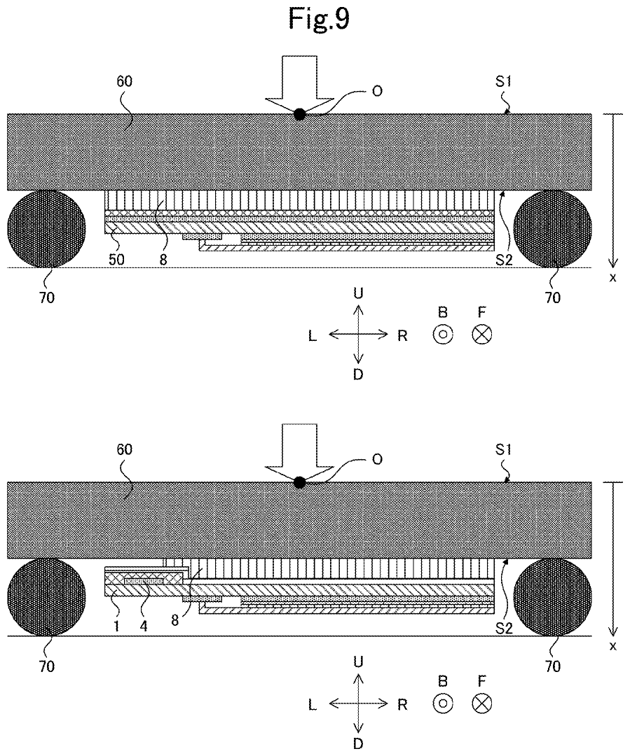

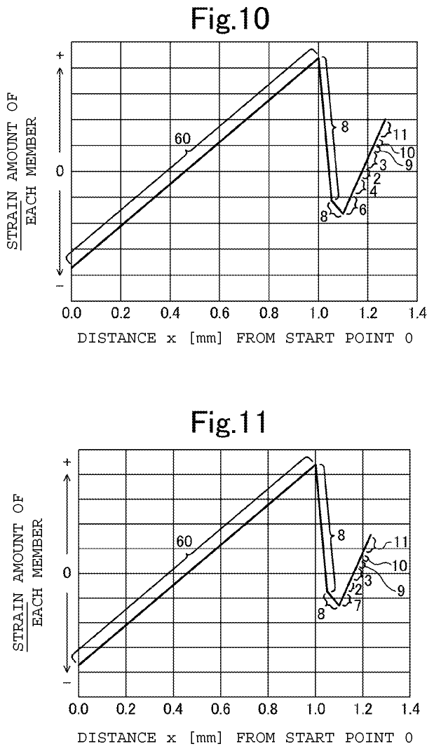

First, the first simulation will be described with reference to the drawings. FIG. 9 is a schematic sectional view of the piezoelectric sensor 50 and the piezoelectric sensor 1 in the first simulation. FIG. 10 is a diagram illustrating a strain amount of each member in the first simulation of the piezoelectric sensor 50. FIG. 11 is a diagram illustrating a strain amount of each member in the first simulation of the piezoelectric sensor 1. The horizontal axis in FIGS. 10 and 11 is the distance x [mm] from the start point O. The vertical axis in FIGS. 10 and 11 is the strain amount of each member.

As illustrated in FIG. 9, in the first simulation, first, a plate 60 having the first main surface S1 and the second main surface S2 is prepared. The plate 60 is a measurement object. The plate 60 was made of Steel Use Stainless (SUS). Next, either the piezoelectric sensor 1 or the piezoelectric sensor 50 was attached to the center portion of the second main surface S2 of the plate 60 with the double-sided tape 8. Next, each of the left end portion and the right end portion of the plate 60 was supported by a support member 70. Thereafter, the center portion (start point O) of the first main surface S1 was pressed, and a change in sensitivity to deformation due to a variation in thickness of each member was confirmed. The pressed portion (start point O) and the second electrode 4 do not overlap each other when viewed in the vertical direction. In the first simulation, the thickness of the plate 60 was 1 mm. The double-sided tape 8 had a thickness of 100 μm.

In FIGS. 10 and 11, each member is compressed in a region where the strain amount is negative. In addition, in a region where the strain amount is positive, each member is stretched. When the strain amount is zero, each member is neither compressed nor stretched. As illustrated in FIG. 10, for example, in the case of the plate 60 in the first simulation of the piezoelectric sensor 50, the plate was compressed in a range where the distance x from the start point O is longer than 0.0 mm and shorter than about 0.46 mm. In addition, the plate was stretched in a range where the distance x from the start point O is longer than about 0.46 mm and is 1.0 mm or less. In addition, the plate was neither compressed nor stretched at a position where the distance x from the start point O is about 0.46 mm. In other words, when the center portion (start point O) of the first main surface S1 was pressed, the upper portion (range where the distance x from the start point O is longer than 0.0 mm and shorter than about 0.46 mm) of the plate 60 was compressed, the lower portion (range where the distance x from the start point O is longer than 0.0 mm and is about 0.46 mm or less) of the plate 60 was stretched, and the boundary surface between the upper portion and the lower portion of the plate 60 (the portion where the distance x from the start point O is about 0.46 mm) was neither compressed nor stretched. In this case, the boundary surface between the upper portion and the lower portion of the plate 60 (the portion where the distance x from the start point O is about 0.46 mm) is the neutral surface of the stress.

In the first simulation of the piezoelectric sensor 50, the neutral surface of the stress is located on each of the plate 60, the double-sided tape 8, and the FPC 2. Each of the coverlay 6 and the second electrode 4 was entirely compressed. Each of the first electrode 3, the hot melt 9, the piezoelectric film 10, and the shield tape 11 was entirely stretched.

As illustrated in FIG. 11, in the first simulation of the piezoelectric sensor 1, the neutral surface of the stress is located on each of the plate 60, the double-sided tape 8, and the first electrode 3. Each of the shield film 7 and the FPC 2 was entirely compressed. Each of the hot melt 9, the piezoelectric film 10, and the shield tape 11 was entirely stretched. Therefore, the FPC 2 in the piezoelectric sensor 1 was not located in the range from the piezoelectric film 10 to the neutral surface of the stress closest to the piezoelectric film 10 (neutral surface of the stress located in the first electrode 3).

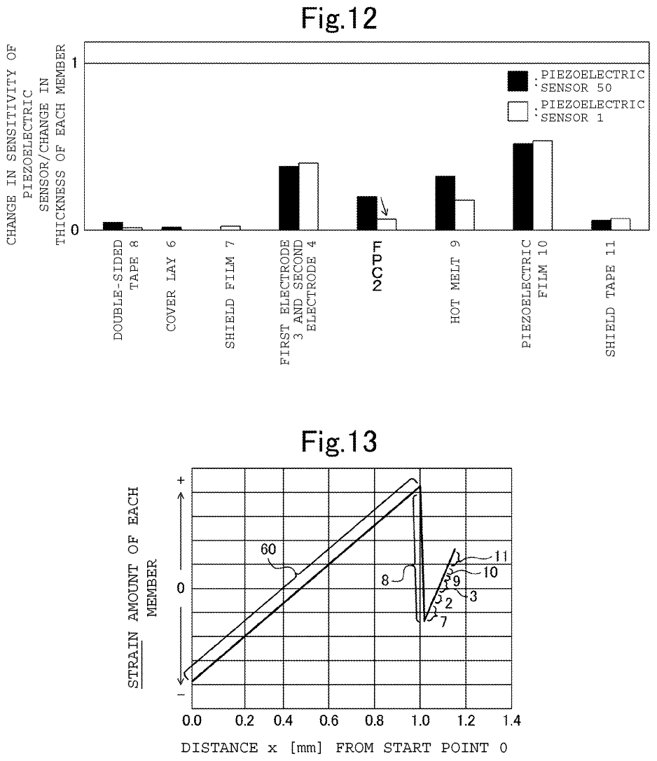

FIG. 12 is a diagram illustrating a change in sensitivity of the piezoelectric sensor 50 and the piezoelectric sensor 1 with respect to a change in thickness of each member of the piezoelectric sensor 50 and the piezoelectric sensor 1 in the first simulation. A vertical axis in FIG. 12 is a change in sensitivity of the piezoelectric sensor 50 and the piezoelectric sensor 1 with respect to a change in thickness of each member of the piezoelectric sensor 50 and the piezoelectric sensor 1. For example, if the sensitivity of the piezoelectric sensor 50 changes by 1% when the thickness of the double-sided tape 8 of the piezoelectric sensor 50 changes by 1%, the change in the sensitivity of the piezoelectric sensor 50 with respect to the change in the thickness of the double-sided tape 8 of the piezoelectric sensor 50 is 1. If the sensitivity of the piezoelectric sensor 50 changes by 0.5% when the thickness of the double-sided tape 8 of the piezoelectric sensor 50 changes by 1%, the change in the sensitivity of the piezoelectric sensor 50 with respect to the change in the thickness of the double-sided tape 8 of the piezoelectric sensor 50 is 0.5.

As illustrated in FIG. 12, in the piezoelectric sensor 50, the change in sensitivity of the piezoelectric sensor 50 with respect to the change in the thickness of the FPC 2 was about 0.2, whereas in the piezoelectric sensor 1, the change in sensitivity of the piezoelectric sensor 1 with respect to the change in the thickness of the FPC 2 was about 0.07. That is, by the first simulation, it has been confirmed that according to the piezoelectric sensor 1, it is possible to suppress a change in sensitivity to a change in the thickness of the FPC 2 as compared with the piezoelectric sensor 50.

In the piezoelectric sensor 1, the first electrode 3, the second electrode 4, and the third electrode 5 do not overlap each other when viewed in the vertical direction in the region A1 where the FPC 2 and the piezoelectric film 10 overlap each other when viewed in the vertical direction. As a result, when the piezoelectric sensor 1 is pressed, the neutral surface of the stress is not located on the FPC 2. In addition, when the piezoelectric sensor 1 is pressed, it is possible to prevent the FPC 2 from being positioned in a range from the piezoelectric film 10 to a neutral surface of stress closest to the piezoelectric film 10 (neutral surface of stress positioned at the first electrode 3). As a result, according to the piezoelectric sensor 1, it is possible to suppress a change in sensitivity to deformation due to a variation in the thickness of the FPC 2.

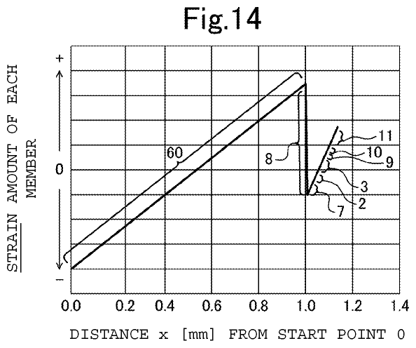

Next, the second simulation will be described with reference to the drawings. FIG. 13 is an example of a diagram illustrating the strain amount of each member in the second simulation of the piezoelectric sensor 1. FIG. 13 illustrates a case where the double-sided tape 8 has a thickness of 20 μm. FIG. 14 is an example of a diagram illustrating the strain amount of each member in the second simulation of the piezoelectric sensor 1. FIG. 14 illustrates a case where the double-sided tape 8 has a thickness of 10 μm. The horizontal axis in FIGS. 13 and 14 is the distance x [mm] from the start point O. The vertical axis in FIGS. 13 and 14 is the strain amount of each member.

In the second simulation, the thickness of the plate 60 was 1 mm as in the first simulation. In the second simulation, the simulation was performed in two ways of a case where the thickness of the double-sided tape 8 was 20 μm or 10 μm.

As illustrated in FIG. 13, when the thickness of the double-sided tape 8 is 20 μm, the neutral surface of the stress is located on each of the plate 60, the double-sided tape 8, and the first electrode 3. Each of the shield film 7 and the FPC 2 was entirely compressed. Each of the hot melt 9, the piezoelectric film 10, and the shield tape 11 was entirely stretched. Therefore, the FPC 2 in the piezoelectric sensor 1 was not located in the range from the piezoelectric film 10 to the neutral surface of the stress closest to the piezoelectric film 10 (neutral surface of the stress located in the first electrode 3).

As illustrated in FIG. 14, even when the thickness of the double-sided tape 8 is 10 μm, the neutral surface of the stress is located on each of the plate 60, the double-sided tape 8, and the first electrode 3. Each of the shield film 7 and the FPC 2 was entirely compressed. Each of the hot melt 9, the piezoelectric film 10, and the shield tape 11 was entirely stretched. Therefore, the FPC 2 in the piezoelectric sensor 1 was not located in the range from the piezoelectric film 10 to the neutral surface of the stress closest to the piezoelectric film 10 (neutral surface of the stress located in the first electrode 3).

However, with respect to the first electrode 3, the neutral surface of the stress is located in the vicinity of the lower surface, and when the thickness of the double-sided tape 8 is made thinner than 10 μm, the neutral surface of the stress is located at the FPC 2 similarly to the piezoelectric sensor 50. Therefore, the thickness of the double-sided tape 8 is desirably 10 μm or more. Even if the double-sided tape 8 is thickened, the neutral surface of the stress is located at the first electrode 3 and is not located at the FPC 2. Therefore, even if the double-sided tape 8 is thickened, the FPC 2 in the piezoelectric sensor 1 is not located in the range from the piezoelectric film 10 to the neutral surface of the stress closest to the piezoelectric film 10 (neutral surface of the stress located at the first electrode 3). However, when the double-sided tape 8 is thickened, the piezoelectric sensor 1 becomes thicker. Therefore, when the piezoelectric sensor 1 is incorporated in a device, it is desirable that the thickness of the double-sided tape 8 be 200 μm or less in order not to hinder thinning of the device.

In the piezoelectric sensor 1, the shield tape 11 is electrically connected to the third electrode 5. As a result, the shield tape 11 is connected to the ground potential. As a result, according to the piezoelectric sensor 1, it is possible to suppress transmission of noise caused by a potential difference generated by the piezoelectric film 10 to an external device and transmission of noise generated by the external device to the piezoelectric film 10. When viewed in the vertical direction, the shield tape 11 overlaps the entire piezoelectric film 10. Therefore, according to the piezoelectric sensor 1, it is possible to further suppress transmission of noise caused by a potential difference generated by the piezoelectric film 10 to an external device and transmission of noise generated by the external device to the piezoelectric film 10.

In the piezoelectric sensor 1, the shield film 7 overlaps the entire piezoelectric film 10 when viewed in the vertical direction. Therefore, according to the piezoelectric sensor 1, it is possible to further suppress transmission of noise caused by a potential difference generated by the piezoelectric film 10 to an external device and transmission of noise generated by the external device to the piezoelectric film 10.

### First modification

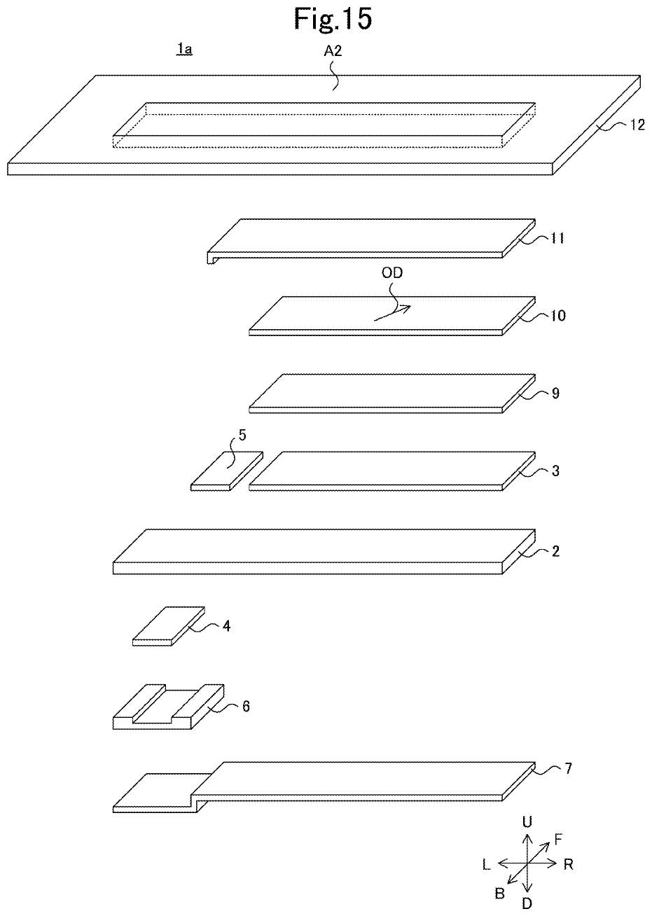

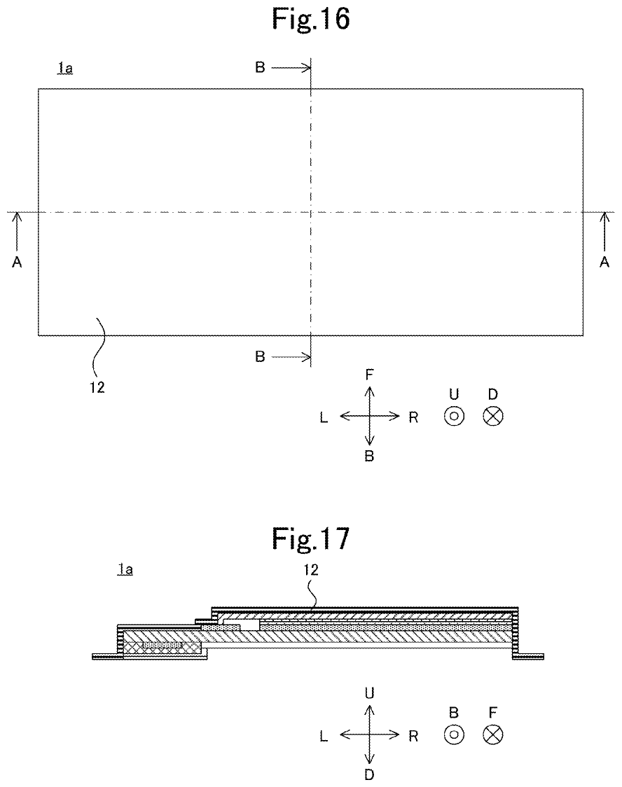

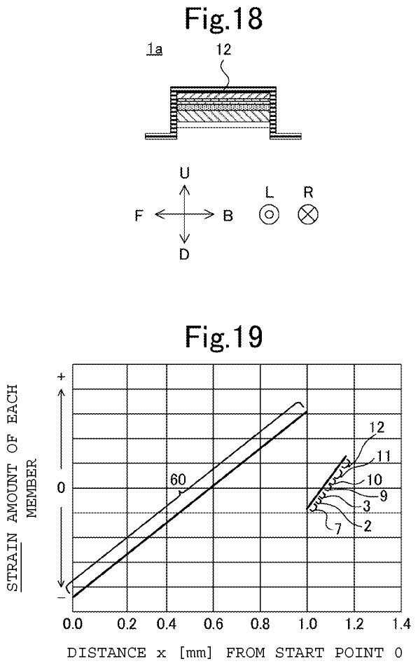

Hereinafter, a configuration of a piezoelectric sensor 1a according to a first modification of the present disclosure will be described with reference to the drawings. FIG. 15 is an exploded perspective view of the piezoelectric sensor 1a. FIG. 16 is a plan view of the piezoelectric sensor 1a. FIG. 17 is a sectional view taken along line A-A in FIG. 16. FIG. 18 is a sectional view taken along line B-B in FIG. 16. In the piezoelectric sensor 1a according to the first modification, only portions different from those of the piezoelectric sensor 1 according to the first embodiment will be described, and the other portions will be omitted. In FIGS. 17 and 18, reference numerals of the FPC 2, the first electrode 3, the second electrode 4, the third electrode 5, the coverlay 6, the shield film 7, the piezoelectric film 10, and the shield tape 11 are omitted.

As illustrated in FIG. 15, the piezoelectric sensor 1a according to the first modification is different from the piezoelectric sensor 1 according to the first embodiment in that a second adhesive member 12 is provided instead of the double-sided tape 8.

The second adhesive member 12 has flexibility. The second adhesive member 12 has a flat film shape. The lower surface of the second adhesive member 12 has adhesiveness. The second adhesive member 12 is disposed on the upper main surface US11 of the shield tape 11. When viewed in the vertical direction, the second adhesive member 12 has a region A2 that does not overlap the FPC 2 and the piezoelectric film 10. In the present modification, the region A2 that does not overlap the FPC 2 and the piezoelectric film 10 has an annular shape when viewed in the vertical direction. As illustrated in FIGS. 16 to 18, the second adhesive member 12 covers the FPC 2, the first electrode 3, the second electrode 4, the third electrode 5, the coverlay 6, the shield film 7, the piezoelectric film 10, and the shield tape 11 by being partially bent. As a result, in the piezoelectric sensor 1a, the second adhesive member 12 fixes the FPC 2, the first electrode 3, the second electrode 4, the third electrode 5, the coverlay 6, the shield film 7, the piezoelectric film 10, and the shield tape 11 to the measurement object. When the piezoelectric sensor 1a is in use, the lower surface of the second adhesive member 12 is brought into close contact with the measurement object to attach the piezoelectric sensor 1a to the measurement object. The shape and arrangement of the second adhesive member according to the present disclosure are not limited to the shape and arrangement of the second adhesive member 12. The upper surface of the second adhesive member 12 may have adhesiveness.

The inventor of the present application conducted a simulation (hereinafter, referred to as a third simulation) for confirming a change in sensitivity to deformation due to a variation in thickness of the FPC 2 for the piezoelectric sensor 1a. Hereinafter, the third simulation will be described with reference to the drawings. FIG. 19 is a diagram illustrating a strain amount of each member in the third simulation of the piezoelectric sensor 1a. The horizontal axis in FIG. 19 is the distance x [mm] from the start point O. The vertical axis in FIG. 19 is the strain amount of each member. Note that the method of the third simulation is similar to the method of the first simulation. However, in the third simulation, the piezoelectric sensor 1a is attached to the central portion of the second main surface S2 of the plate 60 by the second adhesive member 12.

As illustrated in FIG. 19, in the piezoelectric sensor 1a, the neutral surface of the stress is located on each of the plate 60 and the hot melt 9. Each of the shield film 7, the FPC 2, and the first electrode 3 was entirely compressed. Each of the piezoelectric film 10 and the shield tape 11 was entirely stretched. Therefore, the FPC 2 in the piezoelectric sensor 1a was not located in the range from the piezoelectric film 10 to the neutral surface of the stress closest to the piezoelectric film 10 (neutral surface of the stress located in the hot melt 9).

Also in the piezoelectric sensor 1a, when the piezoelectric sensor 1a is pressed, the neutral surface of the stress is not located on the FPC 2. In addition, when the piezoelectric sensor 1a is pressed, it is possible to prevent the FPC 2 from being located in a range from the piezoelectric film 10 to the neutral surface of the stress closest to the piezoelectric film 10 (neutral surface of the stress located at the hot melt 9). As a result, according to the piezoelectric sensor 1a, it is possible to suppress a change in sensitivity to deformation due to a variation in the thickness of the FPC 2.

### Other embodiments

The piezoelectric sensor according to the present disclosure is not limited to the piezoelectric sensors 1 and 1a, and can be changed within the scope of the gist thereof. In addition, the structures of the piezoelectric sensors 1 and 1a may be arbitrarily combined.

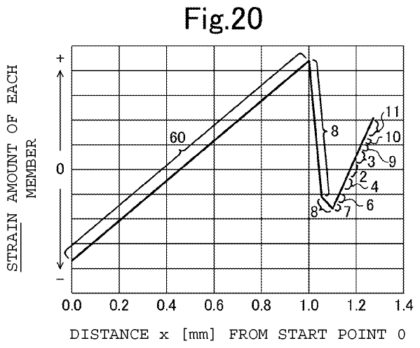

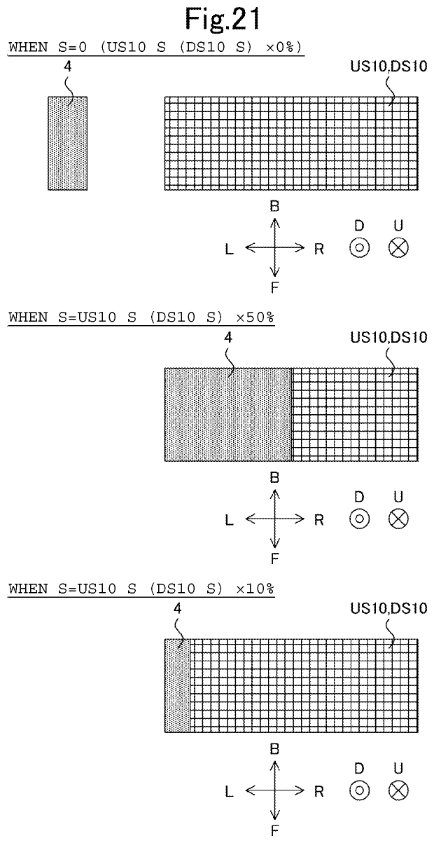

When the pressed portion and the second electrode 4 overlap each other as viewed in the vertical direction, the member where the neutral surface of the stress is located changes. FIG. 20 is a diagram illustrating a strain amount of each member in a simulation of the piezoelectric sensor 1 when the pressed portion overlaps the second electrode 4 as viewed in the vertical direction. FIG. 21 is a plan view illustrating a range in which the second electrode 4 and the piezoelectric film 10 overlap each other when viewed in the upward direction. FIG. 21 illustrates a case where an area US10S of the upper main surface US10 is equal to an area DS10S of the lower main surface DS10.

When the pressed portion overlaps the second electrode 4 as viewed in the vertical direction, the neutral surface of the stress is located on each of the plate 60, the double-sided tape 8, and the FPC 2 as illustrated in FIG. 20. Each of the shield film 7, the coverlay 6, and the second electrode 4 was entirely compressed. Each of the first electrode 3, the hot melt 9, the piezoelectric film 10, and the shield tape 11 was entirely stretched. When the pressed portion overlaps the second electrode 4 as viewed in the vertical direction, the neutral surface of the stress is located at the FPC 2, so that the change in sensitivity to deformation due to the variation in the thickness of the FPC 2 is hardly suppressed.

Here, the piezoelectric film 10 is disposed immediately below the pressed portion. In the case of the piezoelectric sensors 1 and 1a, since the second electrode 4 does not overlap the piezoelectric film 10 when viewed in the vertical direction, the second electrode 4 does not overlap the pressed portion. In contrast, in the case of the piezoelectric sensor 50 according to the comparative example, the second electrode 4 overlaps the piezoelectric film 10 when viewed in the vertical direction, and thus overlaps the pressed portion. Therefore, it is considered that the probability that the change in sensitivity to the change in the thickness of the FPC 2 is suppressed changes depending on the size of the area S of the region where the piezoelectric film 10 and the second electrode 4 overlap when viewed in the vertical direction with respect to the area US10S of the upper main surface US10 or the area DS10S of the lower main surface DS10 of the piezoelectric film 10. That is, as illustrated in FIG. 21, when the area S in which the piezoelectric film 10 and the second electrode 4 overlap when viewed in the vertical direction is 0 (when the area S of the region where the piezoelectric film 10 and the second electrode 4 overlap when viewed in the vertical direction is 0% of the area US10S of the upper main surface US10 or the area DS10S of the lower main surface DS10 of the piezoelectric film 10) as in the piezoelectric sensors 1 and 1a, the probability that the change in sensitivity to the change in the thickness of the FPC 2 is suppressed the most is the highest. In contrast, when the second electrode 4 overlaps the entire piezoelectric film 10 as viewed in the vertical direction (when the area S of the region where the piezoelectric film 10 and the second electrode 4 overlap when viewed in the vertical direction is 100% of the area US10S of the upper main surface US10 or the area DS10S of the lower main surface DS10 of the piezoelectric film 10), the probability that the change in sensitivity to the change in the thickness of the FPC 2 is most suppressed is the lowest. The area S of the region where the piezoelectric film 10 and the second electrode 4 overlap when viewed in the vertical direction is desirably 0% to 50% of the area US10S of the upper main surface US10 or the area DS10S of the lower main surface DS10 of the piezoelectric film 10. The area S of the region where the piezoelectric film 10 and the second electrode 4 overlap when viewed in the vertical direction is desirably 0% to 10% of the area US10S of the upper main surface US10 or the area DS10S of the lower main surface DS10 of the piezoelectric film 10.

### DESCRIPTION OF REFERENCE SYMBOLS

1, 1a: Piezoelectric sensor
2: FPC
3: First electrode
4: Second electrode
5: Third electrode
6: Coverlay
7: Shield film
8: Double-sided tape
9: Hot melt
10: Piezoelectric film
11: Shield tape
12: Second adhesive member
60: Plate
70: Support member
A1, A2: Region
DS2, DS7, DS10, DS11: Lower main surface
DS10S, S, US10S: Area
O: Start point
OD: Uniaxially stretching direction
S1: First main surface
S2: Second main surface
US2, US7, US10, US11: Upper main surface
x: Distance

1. A piezoelectric sensor comprising:
an insulating base material having a first main surface and a second main surface;
a plurality of electrodes including a first electrode on the first main surface;
a piezoelectric film having a third main surface and a fourth main surface, the piezoelectric film being disposed such that the fourth main surface faces the first electrode, wherein
in a region where the insulating base material and the piezoelectric film overlap each other in a plan view of the piezoelectric sensor, the plurality of electrodes do not overlap each other in the plan view.

2. The piezoelectric sensor according to claim 1, further comprising a first adhesive member between the fourth main surface and the first electrode.

3. The piezoelectric sensor according to claim 1, wherein the plurality of electrodes include a second electrode on the second main surface.

4. The piezoelectric sensor according to claim 3, wherein an area of a region where the piezoelectric film and the second electrode overlap in the plan view is 0% to 50% of an area of the third main surface or an area of the fourth main surface.

5. The piezoelectric sensor according to claim 3, wherein an area of a region where the piezoelectric film and the second electrode overlap in the plan view is 0% to 10% of an area of the third main surface or an area of the fourth main surface.

6. The piezoelectric sensor according to claim 3, wherein
the plurality of electrodes include a third electrode on the first main surface, and
the third electrode does not overlap the first electrode and the second electrode in a region where the insulating base material and the piezoelectric film overlap in the plan view.

7. The piezoelectric sensor according to claim 6, wherein an area of a region where the piezoelectric film and the second electrode overlap in the plan view is 0% to 50% of an area of the third main surface or an area of the fourth main surface.

8. The piezoelectric sensor according to claim 6, wherein an area of a region where the piezoelectric film and the second electrode overlap in the plan view is 0% to 10% of an area of the third main surface or an area of the fourth main surface.

9. The piezoelectric sensor according to claim 6, further comprising a first conductive film member on the third main surface, wherein
the first conductive film member is electrically connected to the third electrode.

10. The piezoelectric sensor according to claim 9, wherein the first conductive film member overlaps an entirety of the piezoelectric film in the plan view.

11. The piezoelectric sensor according to claim 9, further comprising a second adhesive member, wherein
the first conductive film member has a fifth main surface and a sixth main surface,
the second adhesive member is on the fifth main surface, and
the second adhesive member has a region not overlapping the insulating base material and the piezoelectric film in the plan view.

12. The piezoelectric sensor according to claim 9, further comprising a second conductive film member having a seventh main surface and an eighth main surface, the second conductive film member being disposed such that the seventh main surface faces the second main surface, wherein
the second conductive film member overlaps an entirety of the piezoelectric film in the plan view.

13. The piezoelectric sensor according to claim 1, further comprising a conductive film member having a fifth main surface and a sixth main surface, the conductive film member being disposed such that the fifth main surface faces the second main surface, wherein
the conductive film member overlaps an entirety of the piezoelectric film in the plan view.

14. The piezoelectric sensor according to claim 1, further comprising:
a second conductive film member having a seventh main surface and an eighth main surface, the second conductive film member being disposed such that the seventh main surface faces the second main surface; and
a third adhesive member on the eighth main surface, wherein
a thickness of the third adhesive member is 10 μm to 200 μm.

15. The piezoelectric sensor according to claim 1, wherein the piezoelectric film comprises polylactic acid stretched in at least one uniaxial direction.

16. A piezoelectric sensor comprising:
an insulating base material having a first main surface and a second main surface;
a first electrode on the first main surface;
a second electrode on the second main surface;
a third electrode on the first main surface; and
a piezoelectric film having a third main surface and a fourth main surface, the piezoelectric film being disposed such that the fourth main surface faces the first electrode, wherein
an area of a region where the piezoelectric film and the second electrode overlap in the plan view is 0% to 50% of an area of the third main surface or an area of the fourth main surface, and
the first electrode, the second electrode and the third electrode do not overlap each other in the plan view.

17. The piezoelectric sensor according to claim 16, wherein the area of the region where the piezoelectric film and the second electrode overlap in the plan view is 0% to 10% of the area of the third main surface or the area of the fourth main surface.

18. The piezoelectric sensor according to claim 16, wherein the third electrode does not overlap the first electrode and the second electrode in a region where the insulating base material and the piezoelectric film overlap in the plan view.

19. The piezoelectric sensor according to claim 16, further comprising a conductive film member on the third main surface, wherein the conductive film member is electrically connected to the third electrode.

20. The piezoelectric sensor according to claim 19, wherein the first conductive film member overlaps an entirety of the piezoelectric film in the plan view.
